(19) United States
(12) Patent Application Publication
(10) Pub. No.: US 2024/0372526 A1
(43) Pub. Date: Nov. 7, 2024

(54) ACOUSTIC WAVE DEVICE

(71) Applicant: Murata Manufacturing Co., Ltd., Nagaokakyo-shi (JP)

(72) Inventor: Yasunobu HAYASHI, Nagaokakyo-shi (JP)

(21) Appl. No.: 18/773,665

(22) Filed: Jul. 16, 2024

Related U.S. Application Data
(63) Continuation of application No. PCT/JP2023/006762, filed on Feb. 24, 2023.

(30) Foreign Application Priority Data
Mar. 29, 2022 (JP) 2022-053802

(51) Int. Cl. H03H 9/145; H03H 9/02

(52) U.S. Cl. CPC H03H 9/14538; H03H 9/02543

(57) ABSTRACT

An acoustic wave device includes a piezoelectric substrate and an IDT electrode including an electrode material layer including a base metal element A and an additive B. A compound represented by AₓB_{y} is included in a region where a concentration of the additive B is about 50 at % or less in a binary phase diagram of the base element A and the additive B, where x and y are any positive numbers. In the binary phase diagram, Ta<Tc and Tb−Ta<300° C., where Ta is a melting point of the base element A, Tb is a melting point of the additive B, and Tc is a melting point of the compound AₓB_{y}. The compound AₓB_{y} segregates in the base element A and grain sizes of the base element A and of the compound AₓB_{y} are about 10 nm or more and about 100 nm or less.

### CROSS REFERENCE TO RELATED APPLICATIONS

This application claims the benefit of priority to Japanese Patent Application No. 2022-053802 filed on Mar. 29, 2022 and is a Continuation application of PCT Application No. PCT/JP2023/006762 filed on Feb. 24, 2023. The entire contents of each application are hereby incorporated herein by reference.

### BACKGROUND OF THE INVENTION

### 1. Field of the Invention

The present invention relates to acoustic wave devices.

### 2. Description of the Related Art

Acoustic wave devices have been widely used as filters for cellular phones. Japanese Unexamined Patent Application Publication No. 2004-260194 discloses a surface acoustic wave (SAW) device as an example of an acoustic wave device. In this SAW device, an interdigital transducer (IDT) electrode is provided on a piezoelectric substrate. The IDT electrode includes Al and a metal that forms an intermetallic compound with Al.

### SUMMARY OF THE INVENTION

When using an alloy material for the IDT electrode in the acoustic wave device as described in Japanese Unexamined Patent Application Publication No. 2004-260194, heat resistance and electric power handling capability are sometimes not improved sufficiently.

Example embodiments of the present invention provide acoustic wave devices each being capable of improving heat resistance and electric power handling capability of an IDT electrode.

In an acoustic wave device according to an example embodiment of the present invention, a piezoelectric substrate and an IDT electrode provided on the piezoelectric substrate are provided, in which the IDT electrode includes a layer including an electrode material including a base element A and an additive B, where A is a metal element being a base element and B is an element being an additive, a state of a compound represented by AₓB_{y} is included in a region where a concentration of the additive B is about 50 at % or less in a binary phase diagram of the base element A and the additive B, where x and y are any positive numbers, in the binary phase diagram, Ta<Tc and Tb−Ta<300° C., where Ta is a melting point of the base element A, Tb is a melting point of the additive B, and Tc is a melting point of the compound AₓB_{y}, in the electrode material, the compound AₓB_{y} segregates in the base element A, and in the electrode material, a grain size of the base element A and a grain size of the compound AₓB_{y} are about 10 nm or more and about 100 nm or less.

In another acoustic wave device according to an example embodiment of the present invention, a piezoelectric substrate and an IDT electrode provided on the piezoelectric substrate are provided, in which the IDT electrode includes a layer including an electrode material including a base element A and an additive B, where A is a metal element being a base element and B is an element being an additive, the electrode material includes a compound represented by AₓB_{y}, where x and y are any positive numbers, the base element A is Al, the additive B is at least one of Ba, Ca, Ce, La, Sb, Sr, Yb, or Pr, and in the electrode material, a grain size of the base element A and a grain size of the compound AₓB_{y} are about 10 nm or more and about 100 nm or less.

In still another example embodiment of an acoustic wave device according to the present invention, a piezoelectric substrate and an IDT electrode provided on the piezoelectric substrate are provided, in which the IDT electrode includes a layer including an electrode material including a base element A and an additive B, where A is a metal element being a base element and B is an element being an additive, a state of a compound represented by AₓB_{y} is included in a region where a concentration of the additive B is about 50 at % or less in a binary phase diagram of the base element A and the additive B, where x and y are any positive numbers, in the binary phase diagram, Ta<Tc, where Ta is a melting point of the base element A, Tb is a melting point of the additive B, and Tc is a melting point of the compound AₓB_{y}, a temperature at 1 Pa vapor pressure of the base element A is higher than a temperature at 1 Pa vapor pressure of the additive B, where a temperature at 1 Pa vapor pressure is a temperature at which a vapor pressure of the base element A or the additive B becomes 1 Pa, in the electrode material, the compound AₓB_{y} segregates in the base element A, and in the electrode material, a grain size of the base element A and a grain size of the compound AₓB_{y} are about 10 nm or more and about 100 nm or less.

In yet another example embodiment of an acoustic wave device according to the present invention, a piezoelectric substrate and an IDT electrode provided on the piezoelectric substrate are provided, in which the IDT electrode includes a layer made of an electrode material including a base element A and an additive B, where A is a metal element being a base element and B is an element being an additive, the electrode material includes a compound represented by AₓB_{y}, where x and y are any positive numbers, the base element A is Al, the additive B is at least one of Ba, Ca, Sb, Sr, Sm, or Dy, and in the electrode material, a grain size of the base element A and a grain size of the compound AₓB_{y} are about 10 nm or more and about 100 nm or less.

With the acoustic wave devices according to example embodiments of the present invention, the heat resistance and the electric power handling capability of the IDT electrode can be improved.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view of an acoustic wave device according to a first example embodiment of the present invention.

FIG. 2 is a schematic plan view of the acoustic wave device according to the first example embodiment of the present invention.

FIG. 3 is a binary phase diagram of Al and Ce.

FIG. 4 is a diagram for describing the Hall-Petch relation and the inverse Hall-Petch relation.

FIGS. 5A to 5D are schematic elevational cross-sectional views for describing an example of a method for manufacturing the acoustic wave device according to the first example embodiment of the present invention.

FIG. 6 is a schematic elevational cross-sectional view of an acoustic wave device according to a second example embodiment of the present invention.

### DETAILED DESCRIPTION OF THE EXAMPLE EMBODIMENTS

Hereinafter, the present invention will be clarified by describing specific example embodiments of the present invention with reference to the drawings.

It should be noted that the example embodiments described in this specification are merely examples, and partial replacement or combination of configurations is possible between different example embodiments.

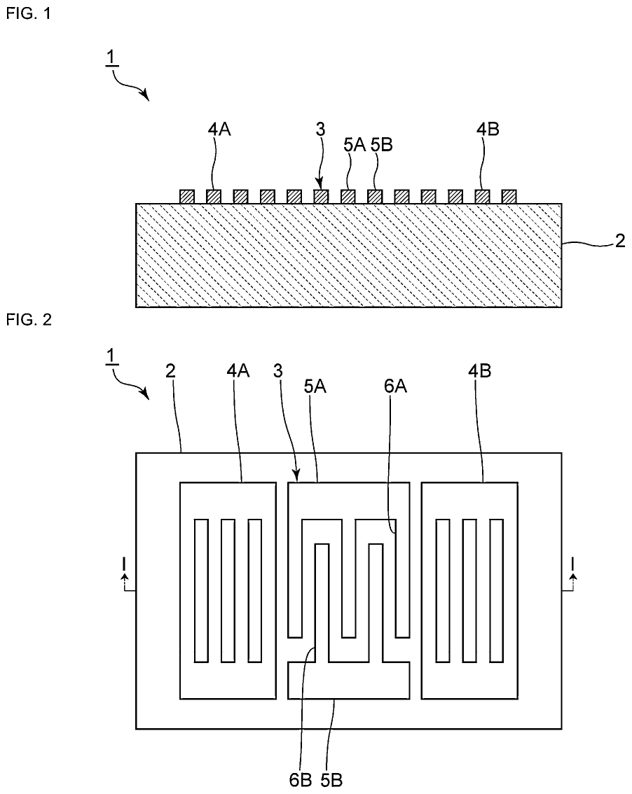

FIG. 1 is a schematic elevational cross-sectional view of an acoustic wave device according to a first example embodiment of the present invention. FIG. 2 is a schematic plan view of the acoustic wave device according to the first example embodiment. Note that FIG. 1 is a schematic cross-sectional view taken along line I-I in FIG. 2.

As illustrated in FIG. 1, the acoustic wave device 1 includes a piezoelectric substrate 2. In the present example embodiment, the piezoelectric substrate 2 is a substrate composed only of a piezoelectric layer. As a material of the piezoelectric layer, for example, lithium tantalate, lithium niobate, zinc oxide, aluminum nitride, quartz crystal, or lead zirconate titanate (PZT), or the like can be used. The piezoelectric substrate 2 may be a laminated substrate including a piezoelectric layer.

An IDT electrode 3 is provided on the piezoelectric substrate 2. Acoustic waves are excited by applying an AC voltage to the IDT electrode 3. A pair of reflectors 4A and 4B are provided on both sides of the IDT electrode 3 on the piezoelectric substrate 2 in an acoustic wave propagation direction. Thus, the acoustic wave device 1 in the present example embodiment is a surface acoustic wave resonator. Note that the acoustic wave device in the present invention is not limited to the acoustic wave resonator, and may be, for example, a filter device or a multiplexer including multiple acoustic wave resonators.

As illustrated in FIG. 2, the IDT electrode 3 includes a first busbar 5A, a second busbar 5B, multiple first electrode fingers 6A, and multiple second electrode fingers 6B. The first busbar 5A and the second busbar 5B face each other. One end of each of the multiple first electrode fingers 6A is connected to the first busbar 5A. One end of each of the multiple second electrode fingers 6B is connected to the second busbar 5B. The multiple first electrode fingers 6A and the multiple second electrode fingers 6B interdigitate with each other. Hereinafter, the first electrode fingers 6A and the second electrode fingers 6B may be collectively referred to as “electrode fingers”.

In the present example embodiment, the IDT electrode 3, the reflector 4A, and the reflector 4B each include a single-layer metal film. However, the IDT electrode 3, the reflector 4A, and the reflector 4B may be each composed of a laminate.

In the present example embodiment, an electrode material of the IDT electrode 3 preferably has all of configurations in 1) to 5) below. 1) The electrode material includes a base element A and an additive B, where A is a metal element that is a base element, and B is an element that is an additive. In this specification, the base element refers to an element that accounts for more than about 50 at % in the electrode material. 2) In a binary phase diagram of the base element A and the additive B, a state of a compound represented by AₓB_{y} is included in a region where a concentration of the additive B is about 50 at % or less, where x and y are any positive numbers. 3) In the binary phase diagram, Ta<Tc and Tb−Ta<300° C., where Ta is a melting point of the base element A, Tb is a melting point of the additive B, and Tc is a melting point of the compound AₓB_{y}. 4) The compound AₓB_{y} segregates in the base element A. 5) A grain size of the base element A and a grain size of the compound AₓB_{y} are about 10 nm or more and about 100 nm or less. Thus, heat resistance and electric power handling capability of the IDT electrode 3 can be improved. This will be described in detail below.

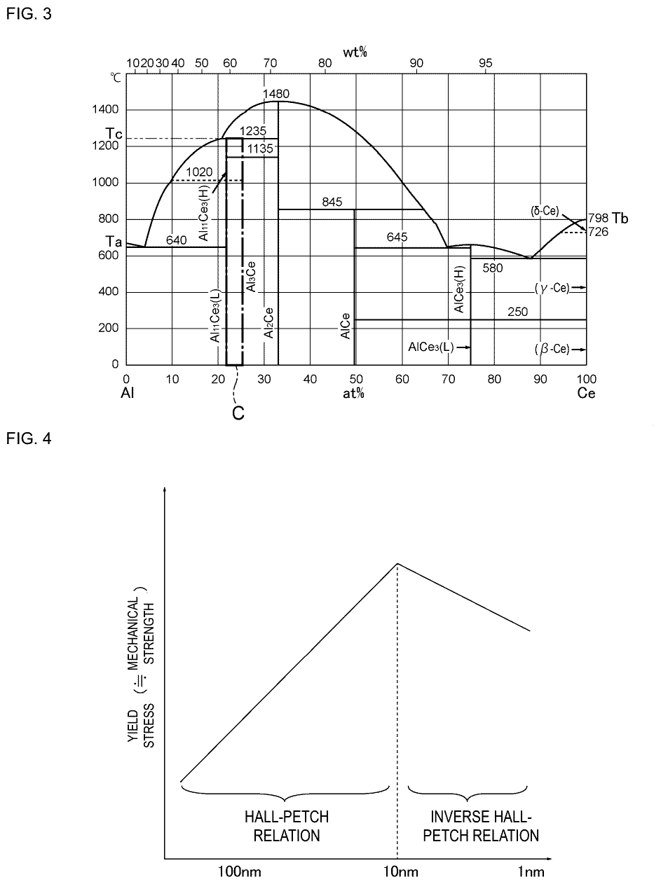

In the present example embodiment, specifically, the base element A in the electrode material of the IDT electrode 3 is Al. The additive B is Ce. A binary phase diagram of the base element Al and the additive Ce is shown in FIG. 3.

FIG. 3 is a binary phase diagram of Al and Ce.

It is understood that a state in region C surrounded by an alternate long and short dash line in FIG. 3 is a state of an intermetallic compound of Al and Ce. In particular, this intermetallic compound is Al₁₁Ce₃. In this compound, x=11 and y=3. In the present example embodiment, both the base element Al and the additive Ce are metals. In the binary phase diagram, region C is included in a region where a concentration of the additive Ce is about 50 at % or less. Thus, as in 2) above, the state of the compound represented by Al₁₁Ce₃ is included in the region where the concentration of the additive Ce is about 50 at % or less in the binary phase diagram of the base element Al and the additive Ce.

A melting point Ta of the base element Al shown in FIG. 3 is about 660° C. A melting point Tb of the additive Ce is about 798° C. A melting point Tc of the compound Al₁₁Ce₃ is about 1235° C. Thus, as in 3) above, Ta<Tc and Tb−Ta=138° C.<300° C.

As in 4) above, in the electrode material of the IDT electrode 3, the compound Al₁₁Ce₃ segregates in the base element Al. As in 5) above, in the electrode material, a grain size of the base element Al and a grain size of the compound Al₁₁Ce₃ are about 10 nm or more and about 100 nm or less.

The states of the base element A and the compound AₓB_{y} in the electrode material of the IDT electrode 3 can be observed using, for example, a transmission electron microscope (TEM). The grain size can also be confirmed by calculating the crystallite size from X-ray diffraction (XRD) using the Scherrer equation.

In the present example embodiment, the heat resistance and the electric power handling capability of the IDT electrode 3 can be improved. This is related to the Hall-Petch relation and the inverse Hall-Petch relation. As shown in FIG. 4, according to the Hall-Petch relation, the smaller a grain size in a material, the larger yield stress of the material. Note that it is also true that the smaller the grain size in the material, the higher mechanical strength of the material. In more detail, when the grain size of the material is small, a ratio of grain boundaries in the material increases. The grain boundaries act as barriers to dislocations. The dislocations cause plastic deformation. Therefore, the more grain boundaries in a material, the less likely the material is to deform plastically. Thus, the Hall-Petch relation holds true. On the other hand, when the grain size is about 10 nm or less, the smaller the grain size of the material, the lower the yield stress of the material. This relation is the inverse Hall-Petch relation. This is due to grain boundary sliding.

In the electrode material of the IDT electrode 3 of the acoustic wave device 1, the grain size of the base element Al and the grain size of the compound Al₁₁Ce₃ are about 10 nm or more and about 100 nm or less, for example. Thus, the mechanical strength of the IDT electrode 3 is high based on the Hall-Petch relation and the inverse Hall-Petch relation. In addition, in the electrode material of the IDT electrode 3, the melting point Tc of the compound Al₁₁Ce₃ is higher than the melting point Ta of the base element Al. Thus, even when high power is applied to the IDT electrode 3 and the IDT electrode 3 becomes a high temperature, the inside of the electrode material is stabilized. Therefore, even when the IDT electrode 3 is at a high temperature, grain sizes of the base element Al and the compound Al₁₁Ce₃ can be kept within the above range, so the IDT electrode 3 is less likely to be damaged. Thus, the heat resistance and the electric power handling capability of the IDT electrode 3 can be improved.

An example of a method for manufacturing the acoustic wave device 1 in the present example embodiment will be described below.

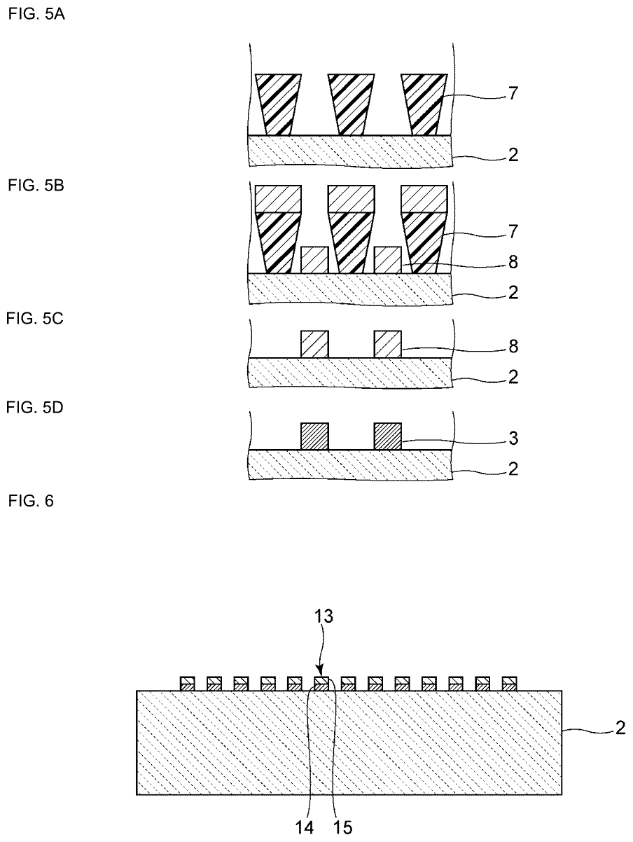

FIGS. 5A to 5D are schematic elevational cross-sectional views for describing an example of a method for manufacturing the acoustic wave device according to the first example embodiment. FIGS. 5A to 5D illustrate the vicinity of a portion corresponding to a pair of electrode fingers.

As illustrated in FIG. 5A, a resist pattern 7 is formed on the piezoelectric substrate 2. Subsequently, as illustrated in FIG. 5B, an alloy film 8 is deposited on the piezoelectric substrate 2 and the resist pattern 7. The alloy film 8 may be deposited by, for example, alloy vapor deposition using an Al—Ce alloy in a form of pellets. At the alloy vapor deposition, a base pressure may be, for example, about 6×10⁻⁴ Pa or less. An acceleration voltage may be, for example, about 10 kV.

Subsequently, the resist pattern 7 is peeled off. Thus, as illustrated in FIG. 5C, the alloy film 8 is patterned. Subsequently, the alloy film 8 is heat-treated. A temperature of the heat treatment may be, for example, about 250° C. or higher and about 290° C. or lower. A time of the heat treatment may be, for example, about 2 hours or more and about 10 hours or less. Thus, the compound Al₁₁Ce₃ is formed. That is, as illustrated in FIG. 5D, the IDT electrode 3 made of the electrode material in the present example embodiment is obtained by the above heat treatment.

As described above, the compound Al₁₁Ce₃ is formed by the appropriate heat treatment.

In the alloy film before the heat treatment, Al and Ce are mixed and laminated. The alloy film is in a supersaturated solid solution state. To be more specific, the base element Al and the additive Ce are solid-solved in a supersaturated state. This is because Al and Ce, which are the deposition materials, are rapidly cooled during deposition of the alloy film.

Subsequent heat treatment separates the alloy in the supersaturated solid solution state into grains of the base element Al and grains of the compound Al₁₁Ce₃. Thus, in the obtained electrode material, the compound Al₁₁Ce₃ segregates in the base element Al. Such a behavior in which the compound segregates in the base element due to the heat treatment from the supersaturated solid solution state occurs only in limited combinations of elements, such as Al and Ce.

In addition, the appropriate heat treatment as exemplified above reduces or prevents coarsening of the grains of the base element Al and the grains of the compound Al₁₁Ce₃ in the electrode material of the IDT electrode 3. On the other hand, when a pure metal is used as the electrode material, it is difficult to reduce or prevent coarsening of grains. For example, when a metal film made of a pure metal is deposited and then heat-treated, the grains of the metal film are likely to be coarsened.

In contrast, as described above, the coarsening of the grains of the base element and the grains of the compound can be reduced or prevented by segregating the compound in the base element through the appropriate heat treatment from the state where the alloy film is a supersaturated solid solution. Thus, as in the present example embodiment, the grain size of the base element Al and the grain size of the compound Al₁₁Ce₃ can be about 10 nm or more and about 100 nm or less, for example.

Further, by satisfying Tb−Ta<300° C., coarsening of the grains of the base element Al and the grains of the compound Al₁₁Ce₃ can be reduced or prevented more reliably. This is thought to be because the melting point Tb of the additive Ce is low, which reduces energy of the entire deposition material and reduces or prevents coarsening of the grains of the deposition material during deposition.

The method for manufacturing the acoustic wave device 1 using a lift-off method has been described above. However, the above manufacturing method is merely an example, and the lift-off method is not necessarily used when forming the IDT electrode 3. For example, after an alloy film is deposited on the piezoelectric substrate 2, a resist pattern may be formed on the alloy film, followed by etching. The deposition of the alloy film is not limited to the alloy vapor deposition and, for example, binary vapor deposition of Al and Ce may be performed, or a sputtering method may be used. Al and Ce may be simultaneously deposited as deposition materials.

In the present example embodiment, an example is illustrated in which the base element A is Al and the additive B is Ce. Note that the base element A and the additive B are not limited to the above. However, the base element A is preferably Al. On the other hand, the additive B is preferably at least one of Ba, Ca, Ce, La, Sb, Sr, Yb, or Pr. Table 1 shows the melting point Tb, the difference in melting points Tb−Ta, the composition formula of the compound AₓB_{y}, and the melting point Tc of the compound AₓB_{y} when Al is used as the base element A and the above elements are used as the additive B.

TABLE 1

| Additive B | Tb [° C.] | Tb − Ta [° C.] | AₓB_{y} | Tc [° C.] |
|---|---|---|---|---|
| Ba | 726 | 66 | Al₄Ba | 1097 |
| Ca | 842 | 182 | Al₄Ca | 700 |
| Ce | 795 | 135 | Al₁₁Ce₃ | 1235 |
| La | 920 | 260 | Al₁₁La₃ | 1240 |
| Sr | 777 | 117 | Al₄Sr | 1040 |
| Sb | 631 | −29 | AlSb | 1050 |
| Yb | 824 | 164 | Al₃Yb | 980 |
| Pr | 935 | 275 | Al₁₁Pr₃ | about 1250 |

When any of the above elements other than Ce is used as the additive B, the heat resistance and the electric power handling capability of the IDT electrode can be improved as in the present example embodiment.

In FIG. 1, a cross section of the electrode fingers taken along a direction orthogonal to a direction in which the electrode fingers extend is schematically illustrated. A cross-sectional shape of each electrode finger is illustrated as a rectangle. That is, side surfaces of the electrode fingers extend parallel to a direction normal to a principal surface of the piezoelectric substrate 2. Note that the side surfaces of the electrode finger are surfaces connected to two surfaces of the electrode finger that face each other in a thickness direction. However, the side surfaces of each electrode finger may be inclined with respect to the direction normal to the principal surface of the piezoelectric substrate 2. The cross-sectional shape of each electrode finger may be, for example, a trapezoid.

A dielectric film may be provided on the piezoelectric substrate 2 so as to cover the IDT electrode 3. In this case, the IDT electrode 3 is less likely to be damaged. For example, silicon oxide, silicon nitride, or silicon oxynitride, or the like, can be used for the dielectric film. When silicon oxide is used for the dielectric film, frequency-temperature characteristics of the acoustic wave device 1 can be improved.

FIG. 6 is a schematic elevational cross-sectional view of an acoustic wave device according to a second example embodiment.

The present example embodiment is different from the first example embodiment in that an IDT electrode 13 is formed of a laminate. Except for the above point, the acoustic wave device in the present example embodiment has the same configuration as the acoustic wave device 1 in the first example embodiment.

The IDT electrode 13 includes a first layer 14 and a second layer 15. To be specific, the first layer 14 is provided on a piezoelectric substrate 2. The second layer 15 is provided on the first layer 14. The first layer 14 is a layer with the same electrode material as in the first example embodiment. The second layer 15 is a low resistance layer. Electrical resistance of the second layer 15 is lower than electrical resistance of the first layer 14.

As described above, the first layer 14 in the present example embodiment is made of the same electrode material as the IDT electrode 3 in the first example embodiment. Thus, heat resistance and electric power handling capability of the IDT electrode 13 can be improved. Further, since the second layer 15 is provided as a low resistance layer, the electrical resistance of the IDT electrode 13 can be lowered.

Note that the number of layers of the IDT electrode 13 may be three or more. Also in this case, the first layer 14 is preferably located closer to the piezoelectric substrate 2 than is the second layer 15. Thus, the heat resistance and the electric power handling capability of the IDT electrode 13 can be improved more reliably.

In the following, a third example embodiment of the invention is presented. The third example embodiment is different from the first example embodiment only in a material of the IDT electrode. Therefore, the drawings and reference numerals used in the description of the first example embodiment will be used in the description of the third example embodiment.

In the third example embodiment described with reference to FIG. 1, a base element A of an IDT electrode 3 is Al. An additive B is at least one of Ba, Ca, Sb, Sr, Sm, or Dy.

The third example embodiment has the configurations in 1), 2), 4), and 5) above in the first example embodiment. That is, as follows. 1) The electrode material includes the base element A and the additive B. 2) In a binary phase diagram of the base element A and the additive B, a state of a compound represented by AₓB_{y} is included in a region where a concentration of the additive B is about 50 at % or less. 4) The compound AₓB_{y} segregates in the base element A. 5) A grain size of the base element A and a grain size of the compound AₓB_{y} are about 10 nm or more and about 100 nm or less, for example.

In addition, the third example embodiment has a configuration in 6) below instead of the configuration in 3) above. 6) A melting point Ta of the base element A is lower than a melting point Tc of the compound AₓB_{y}. That is, Ta<Tc. On the other hand, the melting point Ta of the base element A and the melting point Tb of the additive do not have to satisfy the relation Tb−Ta<300° C.

Further, the third example embodiment has a configuration in 7) below. 7) A temperature at 1 Pa vapor pressure of the base element A is higher than a temperature at 1 Pa vapor pressure of the additive B, where a temperature at 1 Pa vapor pressure is a temperature at which vapor pressure of the base element A or the additive B becomes 1 Pa.

Table 2 shows the temperature at 1 Pa vapor pressure, the composition formula of the compound AₓB_{y}, and the melting point Tc of the compound AₓB_{y}, for the combination of the base element A and the additive B in the third example embodiment. When the base element A is Al, the melting point Ta is about 660° C.

TABLE 2

| | | Temperature at 1 | | |
|---|---|---|---|---|
| | | Pa vapor pressure | | |
| | Element | [° C.] | AₓB_{y} | Tc [° C.] |
| Base element A | Al | 1482 | — | — |
| Additive B | Ba | 911 | Al₄Ba | 1097 |
| | Ca | 864 | Al₄Ca | 700 |
| | Sr | 796 | Al₄Sr | 1040 |
| | Sb | 807 | AlSb | 1050 |
| | Sm | 1001 | Al₃Sm | 1130 |
| | Dy | 1378 | Al₃Dy | about 1100 |

Also in the third example embodiment, heat resistance and electric power handling capability of the IDT electrode 3 can be improved as in the first example embodiment.

Note that the acoustic wave device in the third example embodiment can be obtained, for example, by the manufacturing method illustrated in FIGS. 5A to 5D. In the third example embodiment, the temperature at 1 Pa vapor pressure of the base element A is higher than the temperature at 1 Pa vapor pressure of the additive B. Therefore, when an alloy film 8 illustrated with reference to FIG. 5B is deposited by vapor deposition, vapor pressure of the additive B is higher than vapor pressure of the base element A. Thus, by creating a difference in vapor pressure between the additive B and the base element A, the alloy film 8 can be suitably deposited by vapor deposition.

Also when the combination of the base element A and the additive B is the combination shown in Table 2, the compound AₓB_{y} segregates in the base element A by heat-treating the alloy film 8 illustrated with reference to FIG. 5C.

Also in the second example embodiment illustrated in FIG. 6, the same electrode material as the IDT electrode 3 in the third example embodiment may be used for the first layer 14 of the IDT electrode 13. Also in this case, the heat resistance and the electric power handling capability of the IDT electrode 13 can be improved.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate; and
an IDT electrode provided on the piezoelectric substrate; wherein
the IDT electrode includes a layer including an electrode material including a base element A and an additive B, where A is a metal element being a base element and B is an element being an additive;
a state of a compound represented by AₓB_{y} is included in a region where a concentration of the additive B is about 50 at % or less in a binary phase diagram of the base element A and the additive B, where x and y are any positive numbers;
in the binary phase diagram, Ta<Tc and Tb−Ta<300° C., where Ta is a melting point of the base element A, Tb is a melting point of the additive B, and Tc is a melting point of the compound AₓB_{y};
in the electrode material, the compound AₓB_{y} segregates in the base element A; and
in the electrode material, a grain size of the base element A and a grain size of the compound AₓB_{y} are about 10 nm or more and about 100 nm or less.

2. The acoustic wave device according to claim 1, wherein
the base element A is Al; and
the additive B is at least one of Ba, Ca, Ce, La, Sb, Sr, Yb, or Pr.

3. The acoustic wave device according to claim 1, wherein
the IDT electrode includes a low resistance layer having an electrical resistance lower than an electrical resistance of the layer including the electrode material; and
the layer including the electrode material is closer to the piezoelectric substrate than is the low resistance layer.

4. The acoustic wave device according to claim 1, wherein the piezoelectric substrate includes only a piezoelectric layer or is a laminate substrate including a piezoelectric layer.

5. The acoustic wave device according to claim 1, wherein the acoustic wave device is a surface acoustic wave resonator, a filter device, or a multiplexer.

6. The acoustic wave device according to claim 1, wherein reflectors are provided on both ends of the IDT electrode.

7. An acoustic wave device comprising:
a piezoelectric substrate; and
an IDT electrode provided on the piezoelectric substrate; wherein
the IDT electrode includes a layer including an electrode material including a base element A and an additive B, where A is a metal element being a base element and B is an element being an additive;
the electrode material includes a compound represented by AₓB_{y}, where x and y are any positive numbers;
the base element A is Al;
the additive B is at least one of Ba, Ca, Ce, La, Sb, Sr, Yb, or Pr; and
in the electrode material, a grain size of the base element A and a grain size of the compound AₓB_{y} are about 10 nm or more and about 100 nm or less.

8. The acoustic wave device according to claim 7, wherein
the IDT electrode includes a low resistance layer having an electrical resistance lower than an electrical resistance of the layer including the electrode material; and
the layer including the electrode material is closer to the piezoelectric substrate than is the low resistance layer.

9. The acoustic wave device according to claim 7, wherein the piezoelectric substrate includes only a piezoelectric layer or is a laminate substrate including a piezoelectric layer.

10. The acoustic wave device according to claim 7, wherein reflectors are provided on both ends of the IDT electrode.

11. The acoustic wave device according to claim 7, wherein the acoustic wave device is a surface acoustic wave resonator, a filter device, or a multiplexer.

12. An acoustic wave device comprising:
a piezoelectric substrate; and
an IDT electrode provided on the piezoelectric substrate; wherein
the IDT electrode includes a layer including an electrode material including a base element A and an additive B, where A is a metal element being a base element and B is an element being an additive;
a state of a compound represented by AₓB_{y} is included in a region where a concentration of the additive B is about 50 at % or less in a binary phase diagram of the base element A and the additive B, where x and y are any positive numbers;
in the binary phase diagram, Ta<Tc, where Ta is a melting point of the base element A, Tb is a melting point of the additive B, and Tc is a melting point of the compound AₓB_{y};
a temperature at 1 Pa vapor pressure of the base element A is higher than a temperature at 1 Pa vapor pressure of the additive B, where a temperature at 1 Pa vapor pressure is a temperature at which a vapor pressure of the base element A or the additive B becomes 1 Pa;
in the electrode material, the compound AₓB_{y} segregates in the base element A; and
in the electrode material, a grain size of the base element A and a grain size of the compound AₓB_{y} are about 10 nm or more and about 100 nm or less.

13. The acoustic wave device according to claim 12, wherein
the IDT electrode includes a low resistance layer having an electrical resistance lower than an electrical resistance of the layer including the electrode material; and
the layer including the electrode material is closer to the piezoelectric substrate than is the low resistance layer.

14. The acoustic wave device according to claim 12, wherein the piezoelectric substrate includes only a piezoelectric layer or is a laminate substrate including a piezoelectric layer.

15. The acoustic wave device according to claim 12, wherein reflectors are provided on both ends of the IDT electrode.

16. The acoustic wave device according to claim 12, wherein the acoustic wave device is a surface acoustic wave resonator, a filter device, or a multiplexer.

17. An acoustic wave device comprising:
a piezoelectric substrate; and
an IDT electrode provided on the piezoelectric substrate; wherein
the IDT electrode includes a layer including an electrode material including a base element A and an additive B, where A is a metal element being a base element and B is an element being an additive;
the electrode material includes a compound represented by AₓB_{y}, where x and y are any positive numbers;
the base element A is Al;
the additive B is one element selected from the group consisting of Ba, Ca, Sb, Sr, Sm, and Dy; and
in the electrode material, a grain size of the base element A and a grain size of the compound AₓB_{y} are about 10 nm or more and about 100 nm or less.

18. The acoustic wave device according to claim 17, wherein
the IDT electrode includes a low resistance layer having an electrical resistance lower than an electrical resistance of the layer including the electrode material; and
the layer including the electrode material is closer to the piezoelectric substrate than is the low resistance layer.

19. The acoustic wave device according to claim 17, wherein the piezoelectric substrate includes only a piezoelectric layer or is a laminate substrate including a piezoelectric layer.

20. The acoustic wave device according to claim 17, wherein the acoustic wave device is a surface acoustic wave resonator, a filter device, or a multiplexer.
